(19) United States
(12) Patent Application Publication
(10) Pub. No.: US 2011/0127632 A1
(43) Pub. Date: Jun. 2, 2011

(54) SEMICONDUCTOR MEMORY DEVICES AND METHODS OF MANUFACTURING THE SAME

(75) Inventor: Chin Cheng Yang, Gangshan Town (TW)

(73) Assignee: Macronix International Co., Ltd.

(21) Appl. No.: 12/628,737

(22) Filed: Dec. 1, 2009

(51) Int. Cl. H01L 29/06; H01L 21/762

(52) U.S. Cl. 257/506; 438/424; 257/E29.02; 257/E21.546

(57) ABSTRACT

A semiconductor memory device includes a substrate, a patterned dielectric layer on the substrate, a patterned conductive layer on the patterned dielectric layer, and a plurality of isolation structures to provide electrical isolation for the patterned conductive layer. Each of the isolation structures includes a base in the substrate, a first bank extending from the base to the patterned conductive layer, and a second bank extending from the base to the patterned conductive layer, the first bank and the second bank being separated from each other over the substrate.

### BACKGROUND OF THE INVENTION

The present invention generally relates to a semiconductor device and, more particularly, to a semiconductor memory device with an improved gate coupling coefficient (GCC) and a method of fabricating the same.

Gate coupling coefficient (GCC) is one of the important features of flash memory devices. A flash memory device with a larger GCC may generally achieve higher device efficiency. In the fabrication of a flash memory device, the shallow trench isolation (STI) technique may be applied to form isolation structures for bit isolation and word isolation. Specifically, the STI structures may electrically isolate adjacent two cells in a cell array of the flash memory device. Moreover, the STI structures may affect the GCC of the flash memory device, as will be discussed below.

FIGS. 1A to 1H are schematic cross-sectional views illustrating a conventional method of fabricating a flash memory device. Referring to FIG. 1A, a silicon dioxide (SiO₂) layer 12 serving as a pad oxide layer may be formed on a substrate 11 by a thermal oxidation process. Next, a silicon nitride (Si₃N₄) layer 13 with a thickness “T₀” of approximately 1800 angstroms (Å) may be formed on the pad oxide layer 12 by a deposition process.

Referring to FIG. 1B, portions of the pad oxide layer 12 and portions of the silicon nitride layer 13 may be removed by an etch process, exposing portions 111 of the substrate 11. A patterned silicon nitride layer 13-1 and a patterned pad oxide layer 12-1 after the etch process may together form a plurality of stacked structures 10 separating from one another by the exposed portions 111 in a row direction and extending in a column direction. Each of the stacked structures 10 has a width “W₀” in the row direction.

Referring to FIG. 1C, spacer oxides 14 may be formed on both sides of each of the banks 10 by film deposition and etch.

Referring to FIG. 1D, a trench 15 may be formed between adjacent banks 10 by an etch process, using the spacer oxides 14 as a protection layer to protect the banks 10 sidewall from being etched.

Referring to FIG. 1E, STI structures 16 may be formed by filling the trenches 15 with silicon oxide in a deposition process. A chemical mechanical polishing (CMP) process may thereafter be performed to achieve planarization across the surface of the patterned silicon nitride layer 13-1 and the STI structures 16. The patterned silicon nitride layer 13-1 is then removed.

Referring to FIG. 1F, a poly-silicon layer 17 may be formed on the patterned pad oxide layer 12-1 and planarized with the STI structures 16 by a deposition process followed by a CMP process.

Referring to FIG. 1G, the STI structures 16 may be partially etched, resulting in STI structures 16-1 with a reduced height.

Referring to FIG. 1H, an oxide-nitride-oxide (ONO) layer 18 may be formed on the poly-silicon layer 17 and the STI structures 16-1 by a deposition process. The GCC of the flash memory device is a function of the width W₀, which may now in FIG. 1H coincide with the width of each unit of the poly-silicon layer 17 or each unit of the patterned pad oxide layer 12-1 in the row direction. That is, GCC may increase as the width W₀ increases and may decrease as the width W₀ decreases.

It may therefore be desirable to have a semiconductor memory device that has a relatively large width W₀ and hence an improved GCC. Furthermore, it is the trend in the semiconductor industry to fabricate semiconductor devices with miniaturized dimensions. As the overall dimensions of integrated circuits shrink, the memory dimensions shrink, including the width W₀ in each memory cell, which may adversely affect the GCC of a memory device. It may therefore also be desirable to have a method of manufacturing semiconductor memory devices with an improved GCC by increasing the width W₀.

### BRIEF SUMMARY OF THE INVENTION

The present invention is directed to a semiconductor memory device and a method of manufacturing the same that may achieve relatively high gate coupling coefficient.

Examples of the present invention may provide a semiconductor memory device that comprises a substrate, a patterned dielectric layer on the substrate, a patterned conductive layer on the patterned dielectric layer, and a plurality of isolation structures to provide electrical isolation for the patterned conductive layer. Each of the isolation structures includes a base in the substrate, a first bank extending from the base to the patterned conductive layer, and a second bank extending from the base to the patterned conductive layer, the first bank and the second bank being separated from each other over the substrate.

Examples of the present invention may further provide a semiconductor memory device that comprises a substrate, a patterned dielectric layer on the substrate, an array of conductive units arranged in rows and columns on the patterned dielectric layer, and a plurality of isolation structures to provide electrical isolation for the conductive units. Each of the conductive units includes a first portion on the patterned dielectric layer and a second portion over the patterned dielectric layer. The first portion has a width “W₁” in a row direction and the second portion has a width “W” in the row direction, where W₁ is smaller than W. Furthermore, each of the isolation structures includes a base in the substrate, a first bank extending from the base to one of the conductive units, and a second bank extending from the base to another one of the conductive units immediately adjacent to the one conductive unit in the row direction. The first bank and the second bank are separated from each other over the substrate.

Examples of the present invention may also provide a semiconductor memory device that comprises a substrate, and an array of memory cells arranged in rows and columns on the substrate. Each of the memory cells may include a dielectric unit on the substrate, a conductive unit, a first isolation structure and a second isolation structure. The conductive unit may include a first portion on the dielectric unit and a second portion over the dielectric unit. The first portion has a first width in a row direction and the second portion has a second width in the row direction, where the first width is smaller than the second width. The first isolation structure may include a first bank contiguous with the first portion and the second portion of the conductive unit. Moreover, the second isolation structure may include a second bank contiguous with the first portion and the second portion of the conductive unit. The first bank and the second bank are separated from each other over the substrate.

Some examples of the present invention may provide a method of manufacturing a semiconductor memory device. The method comprises providing a substrate, forming a patterned first dielectric layer on the substrate, forming a patterned second dielectric layer on the patterned first dielectric layer; the patterned first and second dielectric layers exposing portions of the substrate, forming trenches through the exposed portions of the substrate, filling the trenches with a dielectric material to form first isolation trenches and then flattened by CMP process, partially removing the patterned second dielectric layer in height to form a patterned dielectric layer, etching the first isolation trenches to from second isolation trenches each having a head portion and a first and a second shoulder portions on respective sides of the head portion, removing the patterned dielectric layer, forming a patterned conductive layer on the patterned first dielectric layer, the patterned conductive layer being level with the head portions of the second isolation trenches, and forming third isolation trenches by removing the head portions of the second isolation trenches so that each of the third isolation trenches includes the first and second shoulder portions and an exposed surface lower than the first and second shoulder portions.

Additional features and advantages of the present invention will be set forth in portion in the description which follows, and in portion will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention as claimed.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, examples are shown in the drawings. It should be understood, however, that the invention is not limited to the precise arrangements and instrumentalities shown in the examples.

In the drawings:

FIGS. 1A to 1H are schematic cross-sectional views illustrating a conventional method of fabricating a flash memory device;

FIG. 2 is a cross-sectional view of a memory cell in part of a semiconductor memory device in accordance with an example of the present invention; and

FIGS. 3A to 3K are schematic cross-sectional views illustrating a method of fabricating the semiconductor memory device illustrated in FIG. 2.

### DETAILED DESCRIPTION OF THE INVENTION

Reference will now be made in detail to the present examples of the invention illustrated in the accompanying drawings. Wherever possible, the same reference numbers will be used throughout the drawings to refer to the same or like portions. It should be noted that the drawings are in greatly simplified form and are not to precise scale.

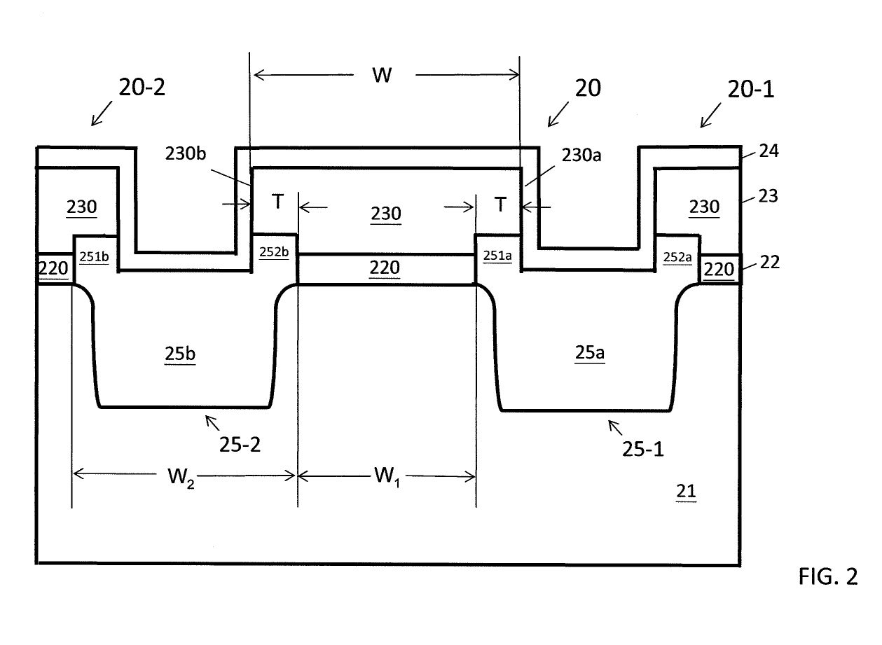

FIG. 2 is a cross-sectional view of a memory cell 20 in part of a semiconductor memory device in accordance with an example of the present invention. The memory cell 20 may serve as a storage unit in the semiconductor memory device that includes an array of such cells 20. For simplicity, only one memory cell in part instead of the whole array of cells of the semiconductor memory device is illustrated.

Referring to FIG. 2, the semiconductor memory device may include a substrate 21, a patterned first dielectric layer 22 further including an array of dielectric units 220, a patterned conductive layer 23 further comprising an array of conductive units 230 arranged in rows and columns, a patterned second dielectric layer 24 and a plurality of isolation structures (only representative isolation structures 25-1 and 25-2 shown). The array of dielectric units 220 may extend in a column direction, i.e., a direction perpendicular to the plane of the page of the diagram of FIG. 2. Furthermore, the representative memory cell 20 may include one of the dielectric units 220, one of the conductive units 230 on the one dielectric unit 220, and a first one 25-1 and a second one 25-2 of the isolation structures.

The one dielectric unit 220, which may include one of silicon oxide (SiO₂) and silicon oxynitride (SiON), may serve as a pad oxide layer or pad dielectric layer for the memory cell 20. The dielectric unit 220 has a width of approximately “W₁” in a row direction, i.e., a direction horizontally across the plane of the page of the diagram of FIG. 2.

The one conductive unit 230, which may include poly-silicon, may serve as floating gate for the memory cell 20. The conductive unit 230 may further include a first portion (not numbered) on the one dielectric unit 220 and a second portion (not numbered) over the one dielectric unit 220. The first portion of the conductive unit 230 has a width of approximately “W₁” in the row direction, and the second portion of the conductive unit 230 has a width of approximately “W” in the row direction, where W₁ is smaller than W.

The first and second isolation structures 25-1 and 25-2, for example, shallow trench isolation (STI) structures, may provide electrical isolation for the memory cell 20. The first isolation structure 25-1 may include a first base 25a in the substrate 21, a first bank 251a extending from the first base 25a to the conductive unit 230 of the memory cell 20, and a second bank 252a extending from the first base 25a to the conductive unit 230 of another memory cell 20-1 immediately adjacent to the memory cell 20 in the row direction. The first bank 251a and the second bank 252a may be separated from each other over the substrate 21. Moreover, the first bank 251a may be flush with a first side 230a of the one conductive unit 230 in the row direction. Furthermore, the first bank 251a is contiguous with the first and second portions of the one conductive unit 230 and has a width of approximately “T” in the row direction.

Likewise, the second isolation structure 25-2 may include a second base 25b in the substrate 21, a first bank 251b extending from the second base 25b to the conductive unit 230 of still another memory cell 20-2 immediately adjacent to the memory cell 20 in the row direction, and a second bank 252b extending from the second base 25b to the conductive unit 230 of the memory cell 20. The first bank 251b and the second bank 252b may be separated from each other over the substrate 21. Moreover, the second bank 252b may be flush with a second side 230b of the one conductive unit 230 in the row direction. Furthermore, the second bank 252b is contiguous with the first and second portions of the one conductive unit 230 and has a width of approximately “T” in the row direction.

In the present example, the dimensional parameters W, W₁ and T satisfy Equation (1) as given below.

W=W₁+2T Equation (1)

The value of “T” may be predetermined so as to prevent short-circuiting between adjacent conductive units 230 during manufacturing processes. In one example, the width T may be equal to or smaller than one third of W₂, i.e., T≦W₂/3. In another example, the width T may range from a quarter of W₂ to one third of W₂, i.e., W₂/4≦T≦W₂/3.

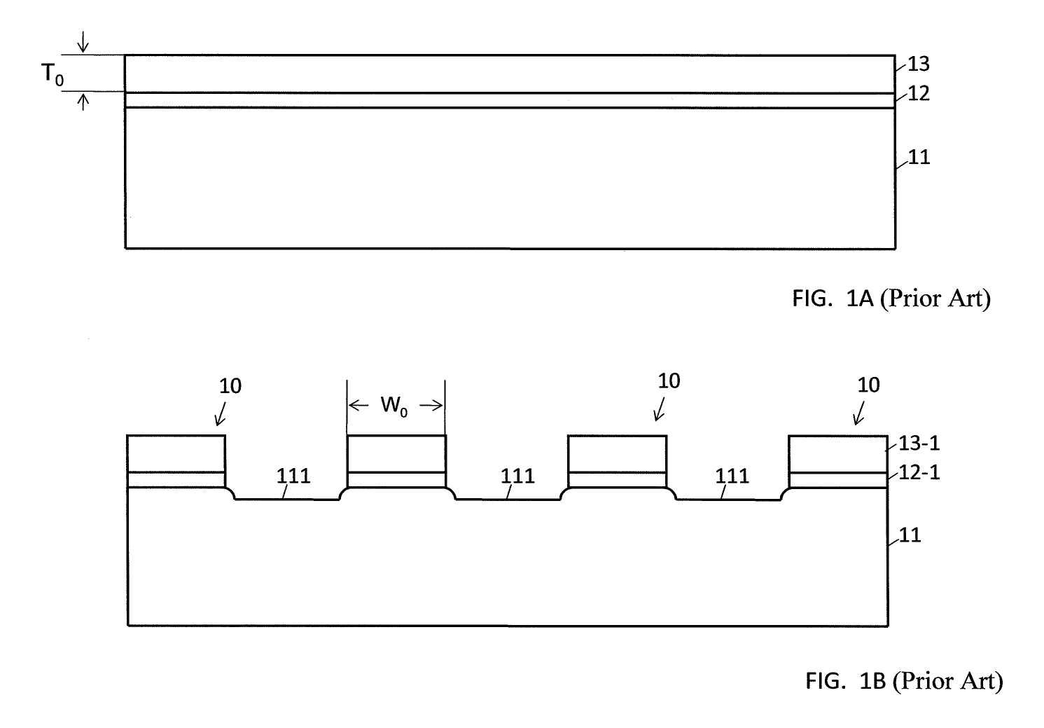

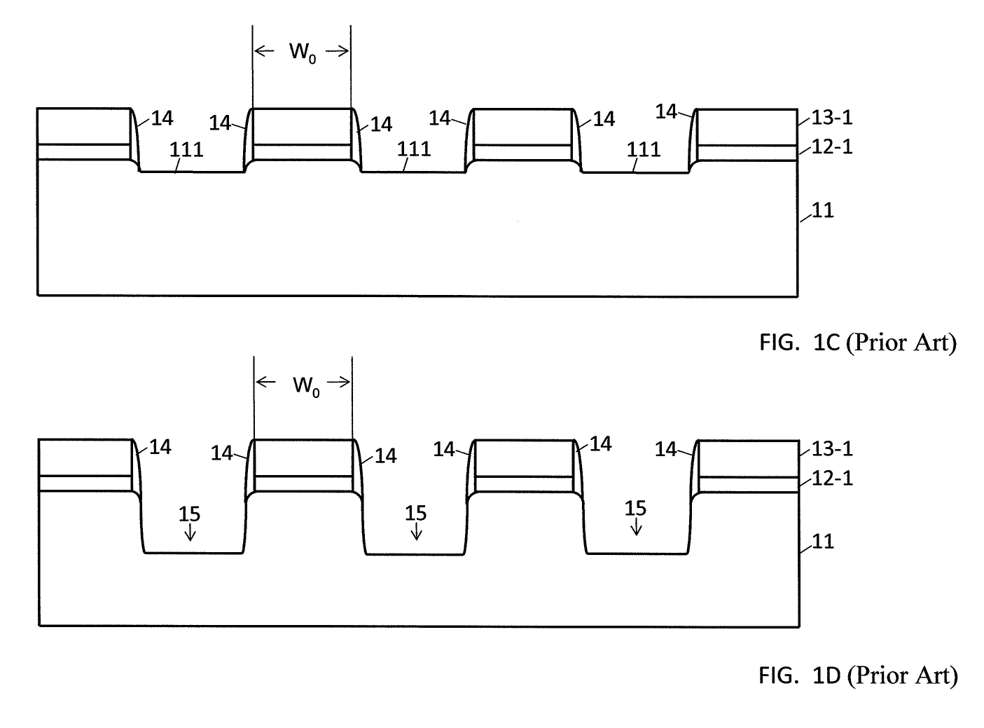

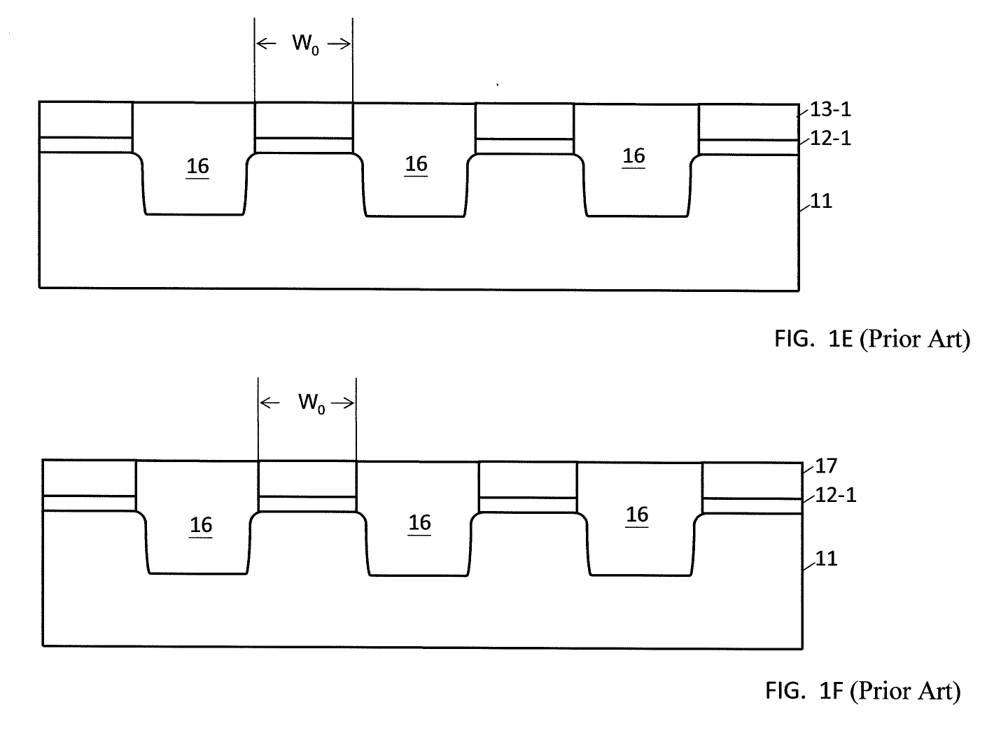

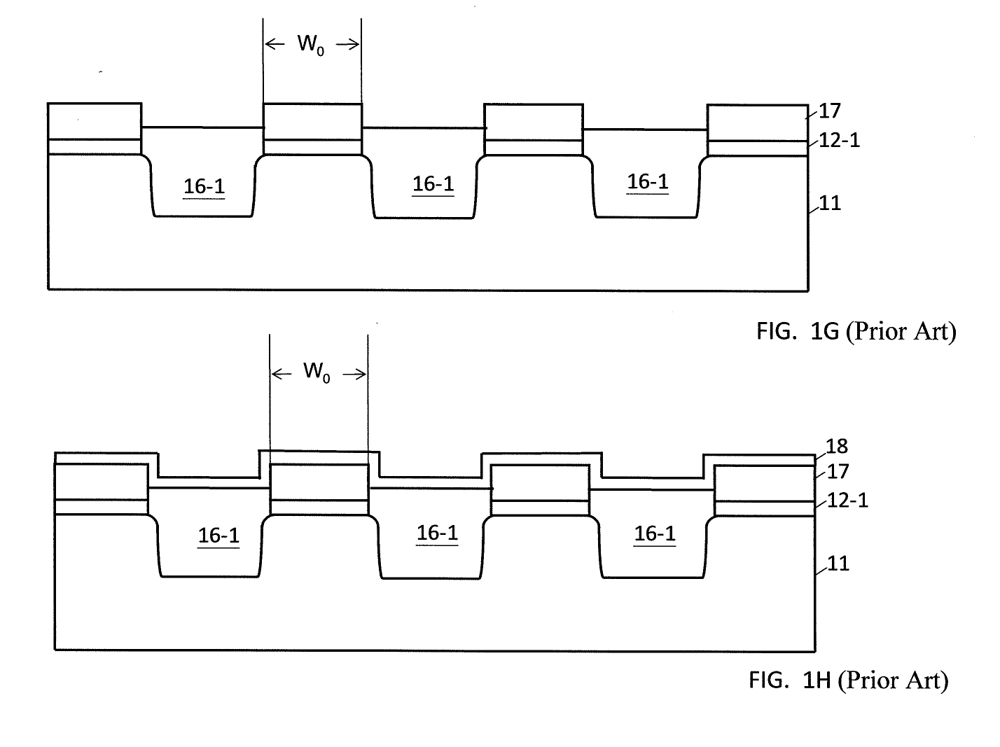

As compared to the semiconductor memory device illustrated in FIG. 1H, the width at issue, i.e., “W,” in the semiconductor memory device according to the present invention is greater that the width “W₀” (which is substantially equal to W₁) in the conventional semiconductor memory device. As a result, the GCC of the semiconductor memory device according to the present invention is greater than that of the conventional semiconductor memory device illustrated in FIG. 1H.

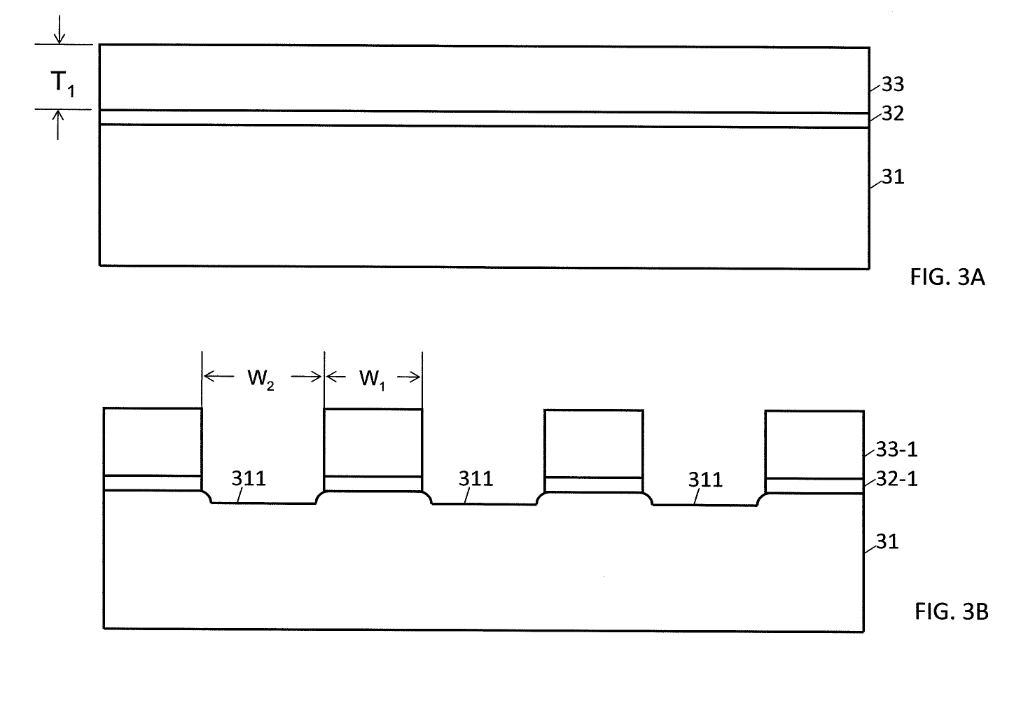

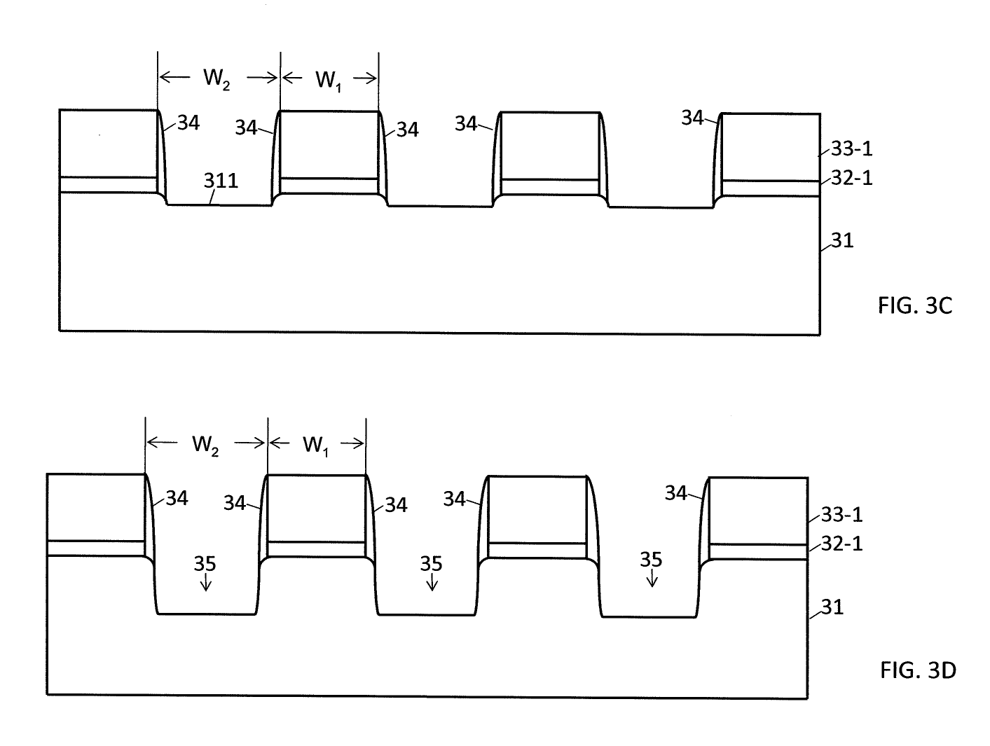

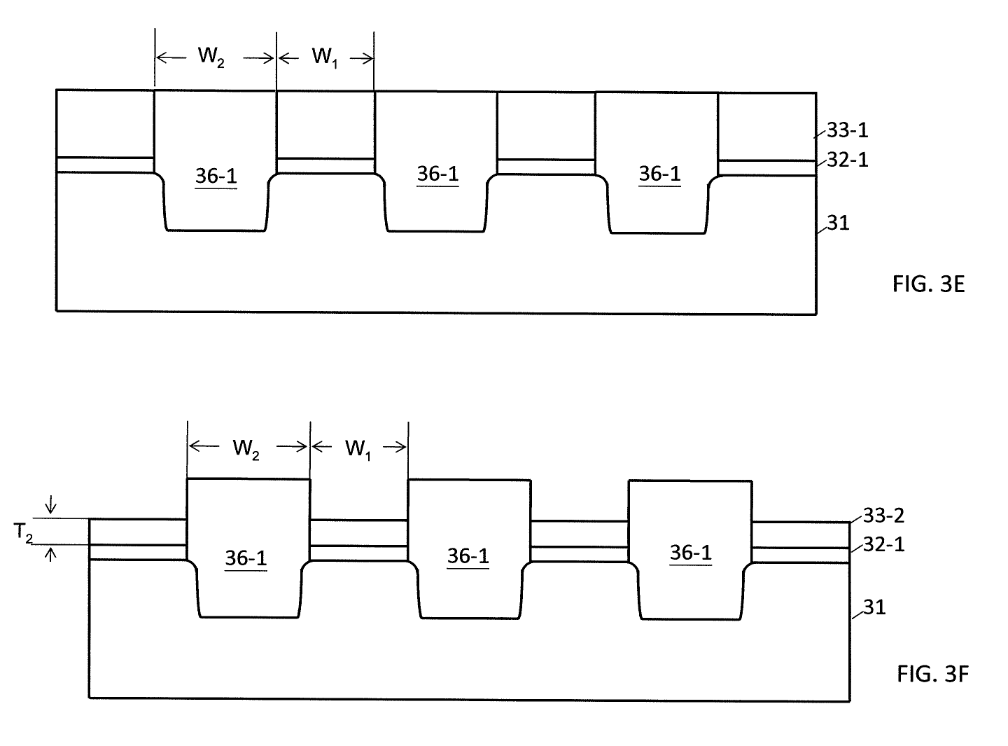

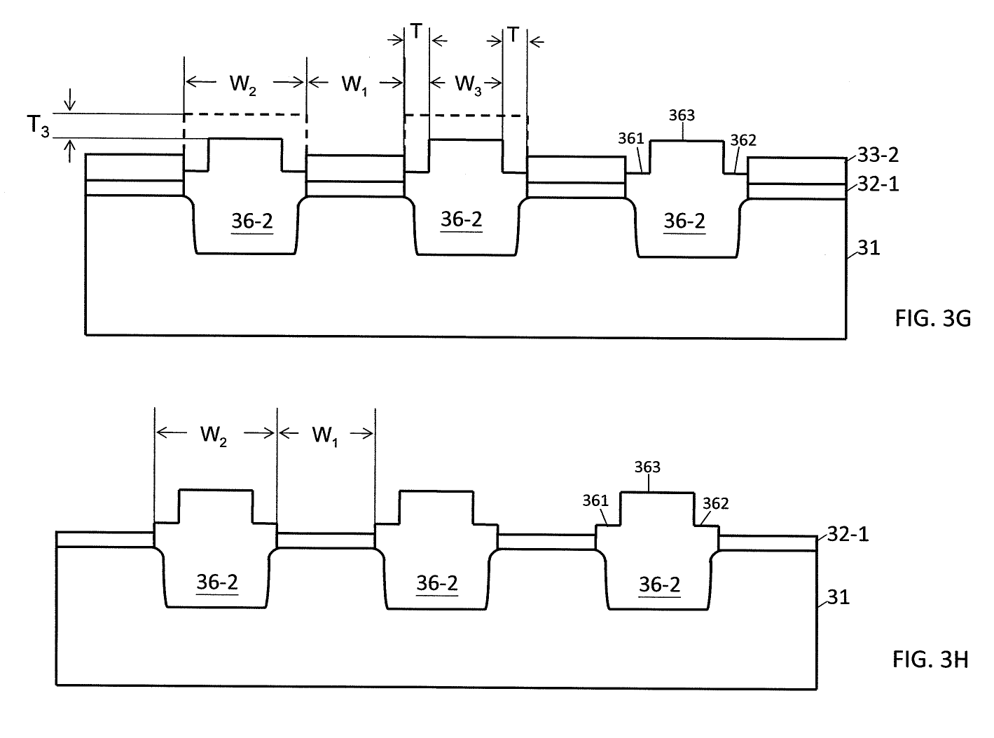

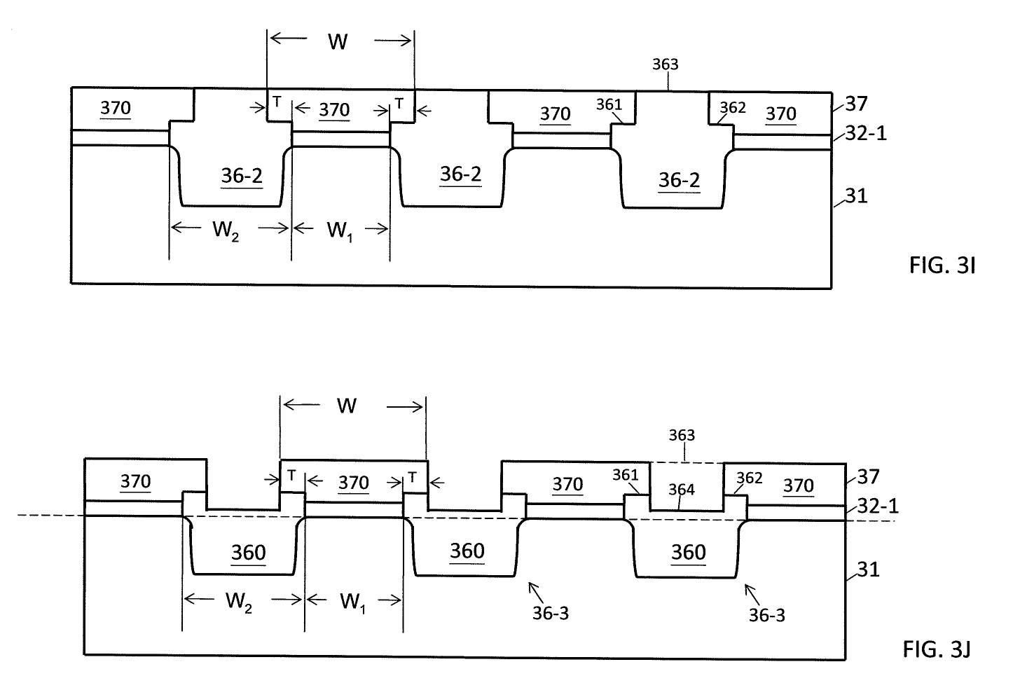

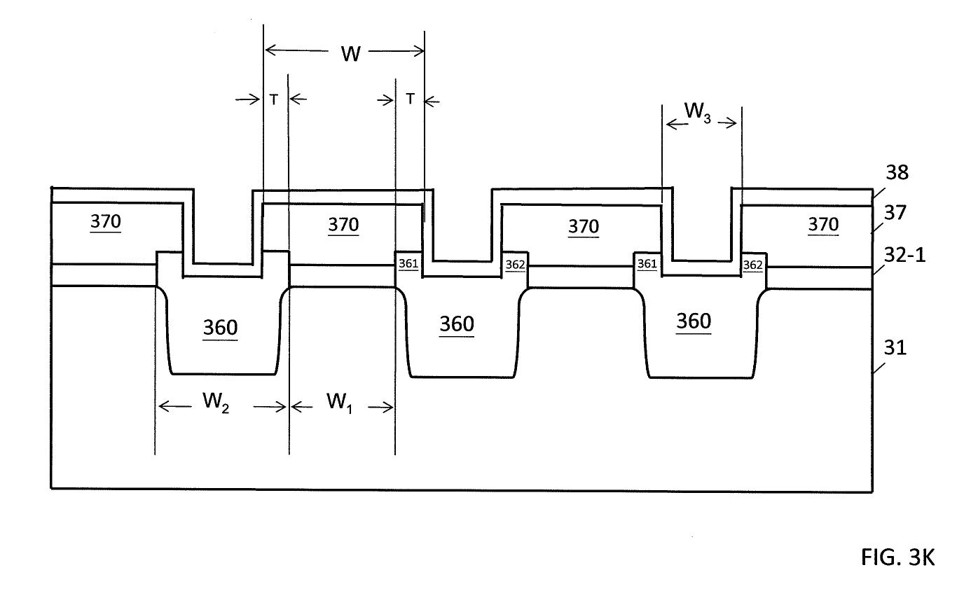

FIGS. 3A to 3K are schematic cross-sectional views illustrating a method of fabricating the semiconductor memory device illustrated in FIG. 2.

Referring to FIG. 3A, a substrate 31 that has been doped with, for example, a p-type impurity, may be provided. Next, a first dielectric layer 32 may be formed on the substrate 31 by, for example, a deposition process. The first dielectric layer 32 may include one of silicon dioxide (SiO₂) and silicon oxynitride (SiON), which has a thickness ranging from approximately 100 angstroms (Å) to 300 Å. Next, a second dielectric layer 33 may be formed on the first dielectric layer 32 by a deposition process. The second dielectric layer 33 in one example may include silicon nitride (SiₓN_{y}) with a thickness “T₁” ranging from approximately 2000 to 3600 Å. The thickness T₁ is greater than the thickness T illustrated in FIG. 1A to facilitate defining features of the semiconductor memory device in subsequent processes.

Referring to FIG. 3B, a patterned second dielectric layer 33-1 and patterned first dielectric layer 32-1 may be formed by a lithography process followed by an etch process. Subsequently, exposing portions 311 of the substrate 31. Each of the patterned first dielectric layer 32-1 and the patterned second dielectric layer 33-1 may have a width “W₁” in a row direction. Furthermore, each of the exposed portions 311 may have a width “W₂” in the row direction. The widths W₁ and W₂ may vary in different generations of processes. For example, in the 90-nanometer (90-nm) process, the width W₁ may be approximately 40 nm while the width W₂ may be approximately 50 nm which is nearly half of the channel length, i.e. 90 nm, of a metal-oxide-semiconductor field effect transistor (MOSFET).

Referring to FIG. 3C, sidewall spacers 34 may be formed along both sidewalls of the patterned first dielectric layer 32-1 and the patterned second dielectric layer 33-1 by a deposition process followed by an etch process. The sidewall spacers 34 may include silicon oxide with a thickness of approximately 200 Å.

Referring to FIG. 3D, a trench 35 may be formed into the substrate 31 through each of the exposed portions 311 using, for example, a shallow trench isolation (STI) technique, wherein the sidewall spacers 34 may function to protect the patterned first dielectric layer 32-1 and the patterned second dielectric layer 33-1 during the trench forming process. Each of the trenches 35 may have a depth ranging from approximately 2000 Å to 3500 Å from the surface of the substrate 31.

Referring to FIG. 3E, the trenches 35 may then be filled with a dielectric material such as silicon oxide by, for example, a high density plasma (HDP) deposition process. Using the patterned second dielectric layer 33-1 as a polish stop layer, a chemical mechanical polishing (CMP) process may be performed to flatten or level the surface of the HDP deposition layer, resulting in first isolation trenches 36-1.

Referring to FIG. 3F, the patterned second dielectric layer 33-1 may then be partially removed or etched back by an etch process, resulting in a patterned dielectric layer 33-2 with a thickness “T₂” of approximately 1800 Å, which may substantially be equal to the thickness T₀ of the silicon nitride layer 13 illustrated in FIG. 1A. The patterned dielectric layer 33-2 exposes portions of each of the first isolation trenches 36-1.

Referring to FIG. 3G, the exposed portions of each of the first isolation trenches 36-1 may be partially removed by, for example, an isotropic etch, resulting in second isolation trenches 36-2 with a height reduced from T₁ by T₃. By controlling the execution time of the isotropic etch process, each of the second isolation trenches 36-2 may include a head portion 363, a first shoulder portion 361 on one side of the head portion 363, and a second shoulder portion 362 on the other side of the head portion 363 in the row direction. Each of the first and second shoulder portions 361 and 362 has a width “T” in the row direction. As previously discussed with reference to FIG. 2, the value of “T” may be predetermined to ensure that the width “W₃” of the head portion 363 in the row direction is large enough so as to prevent short-circuiting between adjacent cells, where W₃ equals W₂ minus 2T. In one example, the width T may be equal to or smaller than one third of W₂, i.e., T≦W₂/3. In another example, the width T may range from a quarter of W₂ to one third of W₂, i.e., W₂/4≦T≦W₂/3.

Referring to FIG. 3H, the patterned dielectric layer 33-2 may be totally removed by an isotropic etch process using H₃PO₄ solution as an etchant.

Referring to FIG. 3I, a conductive layer such as a poly-silicon layer may be formed over the second isolation trenches 36-2 and the patterned first dielectric layer 32-1 by a deposition process and then flattened by a CMP process using the second isolation trenches 36-2 as a polish stop layer, resulting in a patterned conductive layer 37. The patterned conductive layer 37 may include an array of conductive sections 370 extending in the column direction. Each of the conductive sections 370 may include a first section having a width “W₁” on the patterned first dielectric layer 32-1 and a second section having a width “W” in the row direction over the patterned first dielectric layer 32-1, where W substantially equals W₁ plus 2T.

Referring to FIG. 3J, each of the second isolation trenches 36-2 may be partially removed by an etch process such as an oxide dip process using the patterned conductive layer 37 as a mask, resulting in third isolation trenches 36-3. After the etch, the head portions 363 of the second isolation trenches 36-2 may be totally removed so that an exposed surface 364 of each of the third isolation trenches 36-3 is lower than the first and second shoulder portions 361 and 362. The first and second shoulder portions 361 and 362 thus become “banks” with respect to the exposed surface 364. Accordingly, each of the third isolation trenches 36-3 may include a base 360 in the substrate 31 and a first bank 361 and a second bank 362 extending from the base 360.

Referring to FIG. 3K, a third dielectric layer 38 including an oxide-nitride-oxide (ONO) stack may be formed on the patterned conductive layer 37 by a deposition process. Moreover, another conductive layer (not shown) to serve as a control gate layer may be formed over the third dielectric layer 38, and the conductive layer, the third dielectric layer 38 and the patterned conductive layer 37 may be patterned to subsequently form a matrix of memory cells.

It will be appreciated by those skilled in the art that changes could be made to the examples described above without departing from the broad inventive concept thereof. It is understood, therefore, that this invention is not limited to the particular examples disclosed, but it is intended to cover modifications within the spirit and scope of the present invention as defined by the appended claims.

Further, in describing representative examples of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

I claim:

1. A semiconductor memory device comprising:
a substrate;
a patterned dielectric layer on the substrate;
a patterned conductive layer on the patterned dielectric layer; and
a plurality of isolation structures to provide electrical isolation for the patterned conductive layer, each of the isolation structures including a base in the substrate, a first bank extending from the base to the patterned conductive layer, and a second bank extending from the base to the patterned conductive layer, the first bank and the second bank being separated from each other over the substrate.

2. The semiconductor memory device of claim 1, wherein the patterned conductive layer includes an array of conductive units arranged in rows and columns, each of the conductive units having a width “W” in a row direction, and wherein the patterned dielectric layer includes an array of dielectric units each having a width “W₁” in the row direction, the width W₁ being smaller than the width W.

3. The semiconductor memory device of claim 2, wherein the first bank of a first one of the isolation structures extending to a first one of the conductive units has a width “T” in the row direction, and the second bank of a second one of the isolation structures extending to the first one of the conductive units has the width “T”, where W equals W₁ plus 2T.

4. The semiconductor memory device of claim 2, wherein the first bank of a first one of the isolation structures extending to a first one of the conductive units is flush with a first side of the first one conductive unit in the row direction.

5. The semiconductor memory device of claim 4, wherein the second bank of a second one of the isolation structures extending to the first one conductive unit is flush with a second side of the first one conductive unit in the row direction.

6. The semiconductor memory device of claim 2, wherein the first bank of a first one of the isolation structures extends to a first one of the conductive units, and the second bank of the first one isolation structure extends to a second one of the conductive units, the first one and second one conductive units being immediately adjacent to each other in the row direction.

7. The semiconductor memory device of claim 1, wherein each of the isolation structures has a width W₂ across the first bank and second bank thereof in the row direction, and each of the first bank and the second bank has a width “T” in the row direction, where T is equal to or smaller than one third of W₂.

8. The semiconductor memory device of claim 1, wherein each of the isolation structures has a width W₂ across the first bank and second bank thereof in the row direction, and each of the first bank and the second bank has a width “T” in the row direction, where T ranges from a quarter of W₂ to one third of W₂.

9. A semiconductor memory device comprising:
a substrate;
a patterned dielectric layer on the substrate;
an array of conductive units arranged in rows and columns on the patterned dielectric layer, each of the conductive units having a first portion on the patterned dielectric layer and a second portion over the patterned dielectric layer, the first portion having a width “W₁” in a row direction and the second portion having a width “W” in the row direction, W₁ being smaller than W; and
a plurality of isolation structures to provide electrical isolation for the conductive units, each of the isolation structures including a base in the substrate, a first bank extending from the base to one of the conductive units, and a second bank extending from the base to another one of the conductive units immediately adjacent to the one conductive unit in the row direction, the first bank and the second bank being separated from each other over the substrate.

10. The semiconductor memory device of claim 9, wherein patterned dielectric layer includes an array of dielectric units each having the width “W₁” in the row direction.

11. The semiconductor memory device of claim 9, wherein the first bank of a first one of the isolation structures extending to a first one of the conductive units has a width “T” in the row direction, and the second bank of a second one of the isolation structures extending to the first one of the conductive units has the width “T”, where W equals W₁ plus 2T.

12. The semiconductor memory device of claim 9, wherein the first bank of a first one of the isolation structures extending to a first one of the conductive units is flush with a first side of the first one conductive unit in the row direction.

13. The semiconductor memory device of claim 12, wherein the second bank of a second one of the isolation structures extending to the first one conductive unit is flush with a second side of the first one conductive unit in the row direction.

14. The semiconductor memory device of claim 13, wherein each of the first bank of the first one isolation structure and the second bank of the second one isolation structure is contiguous with first portion and the second portion of the first one conductive unit.

15. The semiconductor memory device of claim 9, wherein each of the isolation structures has a width W₂ across the first bank and second bank thereof in the row direction, and each of the first bank and the second bank has a width “T” in the row direction, where T is equal to or smaller than one third of W₂.

16. The semiconductor memory device of claim 9, wherein each of the isolation structures has a width W₂ across the first bank and second bank thereof in the row direction, and each of the first bank and the second bank has a width “T” in the row direction, where T ranges from a quarter of W₂ to one third of W₂.

17. A semiconductor memory device comprising:
a substrate; and
an array of memory cells arranged in rows and columns on the substrate, each of the memory cells comprising:
a dielectric unit on the substrate;
a conductive unit including a first portion on the dielectric unit and a second portion over the dielectric unit, wherein the first portion has a first width in a row direction and the second portion has a second width in the row direction, the first width being smaller than the second width;
a first isolation structure including a first bank contiguous with the first portion and the second portion of the conductive unit; and
a second isolation structure including a second bank contiguous with the first portion and the second portion of the conductive unit, the first bank and the second bank being separated from each other over the substrate.

18. The semiconductor memory device of claim 17, wherein the second width (W) satisfies:
W=W₁+2T
where “W₁” represents the width of the dielectric unit in the row direction, and “T” represents the width of each of the first bank and the second bank in the row direction.

19. A method of manufacturing a semiconductor memory device, the method comprising:
providing a substrate;
forming a patterned first dielectric layer on the substrate;
forming a patterned second dielectric layer on the patterned first dielectric layer; the patterned first and second dielectric layers exposing portions of the substrate;
forming trenches through the exposed portions of the substrate;
filling the trenches with a dielectric material to form first isolation trenches;
partially removing the patterned second dielectric layer in height to form a patterned dielectric layer;
etching the first isolation trenches to from second isolation trenches each having a head portion and a first and a second shoulder portions on respective sides of the head portion;
removing the patterned dielectric layer;
forming a patterned conductive layer on the patterned first dielectric layer, the patterned conductive layer being level with the head portions of the second isolation trenches; and
forming third isolation trenches by removing the head portions of the second isolation trenches so that each of the third isolation trenches includes the first and second shoulder portions and an exposed surface lower than the first and second shoulder portions.

20. The method of claim 19, wherein forming the patterned first and second dielectric layers comprises:
forming a first dielectric layer on the substrate;
forming a second dielectric layer on the first dielectric layer;
patterning the second dielectric layer to form the patterned second dielectric layer; and
patterning the first dielectric layer to form the patterned first dielectric layer.

21. The method of claim 20, wherein the first dielectric layer includes one of silicon oxide and silicon oxynitride and the second dielectric layer includes silicon nitride.

22. The method of claim 19, after filling the trenches with a dielectric material to form first isolation trenches, further comprising:
leveling the first isolation trenches and the patterned second dielectric layer by a chemical-mechanical polish (CMP) process.

23. The method of claim 22, wherein the dielectric material to fill in the trenches includes silicon oxide.

24. The method of claim 19, wherein the patterned conductive layer includes an array of conductive sections each further including a first section on the patterned first dielectric layer and a second section over the patterned first dielectric layer, the first section having a width “W₁” in a reference direction and the second section having a width “W” in the reference direction, where W₁ is smaller than W.

25. The method of claim 24, wherein the first and the second shoulder portions of each of the third isolation trenches have a width “T” in the reference direction, where W equals W₁ plus 2T.

26. The method of claim 25, wherein each of the third isolation trenches has a width “W₂” across the first and second shoulder portions thereof in the reference direction, and T is equal to or smaller than one third of W₂.

27. The method of claim 24, wherein the first shoulder portion of one of the third isolation trenches extends to a first one of the conductive sections, and the second shoulder portion of the one of the third isolation trenches extends to a second one of the conductive sections, the first one and the second one of the conductive sections immediately adjacent to each other in the reference direction.

28. The method of claim 24, wherein the first shoulder portion of a first one of the third isolation trenches extends to one of the conductive sections, and the second shoulder portion of a second one of the third isolation trenches extends to the one conductive section, the first one and the second one of the third isolation trenches immediately adjacent to each other in the reference direction.
